(19) United States
(12) Patent Application Publication
(10) Pub. No.: US 2026/0360423 A1
(43) Pub. Date: Nov. 12, 2026

(54) MEMORY DEVICE AND METHOD OF OPERATING THE SAME

(71) Applicant: SK hynix Inc., Icheon-si (KR)

(72) Inventor: Ung Hee PARK, Icheon-si (KR)

(21) Appl. No.: 19/378,076

(22) Filed: Nov. 3, 2025

(30) Foreign Application Priority Data
May 9, 2025 (KR) 10-2025-0060524

(51) Int. Cl. G11C 13/00

(52) U.S. Cl. CPC G11C 13/0064; G11C 13/0038; G11C 13/0069; G11C 13/0097

(57) ABSTRACT

A method of operating a memory device includes receiving a write command, performing a first write operation on a memory cell, verifying whether the memory cell is turned on or off based on a turn-on verification voltage, and determining whether to perform a second write operation on the memory cell in response to a verification result.

### CROSS-REFERENCE TO RELATED APPLICATION

This application claims priority under 35 U.S.C. §119(a) to Korean Patent Application No. 10-2025-0060524, filed in the Korean Intellectual Property Office on May 9, 2025, the entire contents of which are incorporated herein by reference.

### BACKGROUND

### 1. Technical Field

Embodiments relate to an integrated circuit technology and, more particularly, to a memory device and a method of operating the memory device.

### 2. Related Art

With the recent trends of miniaturization, low power consumption, high performance, and diversification of electronic devices, memory capable of storing information in various electronic devices such as computers and portable communication devices become more desirable. Also, research into memory having various characteristics is also being conducted.

Memory in research may also include memory that is capable of storing data using the characteristics of switching between different resistance states depending on the voltage or current that is applied. Examples of such memory may include Resistive Random Access Memory (RRAM), Phase-change Random Access Memory (PRAM), Ferroelectric Random Access Memory (FRAM), Magnetic Random Access Memory (MRAM), E-fuse, Selector Only Memory (SOM), and the like.

### SUMMARY

In an embodiment, a method of operating a memory device may include receiving a write command, performing a first write operation on a memory cell, verifying whether the memory cell is turned on or off based on a turn-on verification voltage, and determining whether to perform a second write operation on the memory cell in response to a verification result.

In an embodiment, the write command is a reset write command, the first write operation is a first reset write operation to write the memory cell to a reset state, the turn-on verification voltage has a level higher than that of a read voltage, the second write operation is a second reset write operation.

In an embodiment, a method of operating a memory device may include receiving a write command and write data, determining whether the write data is set data or reset data, performing a first set write operation on a first memory cell upon determining that the write data is the set data, performing a first reset write operation on a second memory cell upon determining that the write data is the reset data, verifying whether the first memory cell is turned on or off based on a first turn-on verification voltage, verifying whether the second memory cell is turned on or off, based on a second turn-on verification voltage, the second turn-on verification voltage having a level higher than that of the first turn-on verification voltage, determining whether to perform a second set write operation on the first memory cell in response to a first verification result on the first memory cell, and determining whether to perform a second reset write operation on the second memory cell in response to a second verification result on the second memory cell.

In an embodiment, a memory device may include a memory cell, a control circuit configured to perform a first write operation on the memory cell based on write data and perform a second write operation on the memory cell based on sensing data, and a sensing circuit configured to verify whether the memory cell is turned on or off based on one of a first turn-on verification voltage and a second turn-on verification voltage and to output turn-on information of the memory cell as the sensing data, under control of the control circuit.

### BRIEF DESCRIPTION OF THE DRAWINGS

FIG. 1 is a diagram for describing a memory cell of a memory device according to an embodiment of the present disclosure.

FIGS. 2 and 3 are each diagrams for describing a write operation of a memory device according to an embodiment of the present disclosure.

FIG. 4 is a diagram for describing a read operation of a memory device according to an embodiment of the present disclosure.

FIG. 5 is a flowchart for describing a method of operating a memory device according to an embodiment of the present disclosure.

FIG. 6 is a diagram for describing a turn-on verification operation of a memory device according to an embodiment of the present disclosure.

FIG. 7 is a diagram for describing the configuration of a memory device according to an embodiment of the present disclosure.

FIGS. 8 and 9 are each diagrams for describing changes in the levels of a bit line and a word line depending on the operation of a memory device according to an embodiment of the present disclosure.

### DETAILED DESCRIPTION

Hereinafter, embodiments according to the technical spirit of the present disclosure will be described with reference to the accompanying drawings.

Embodiments of the present disclosure relate to technology provided to improve the distribution of memory cells.

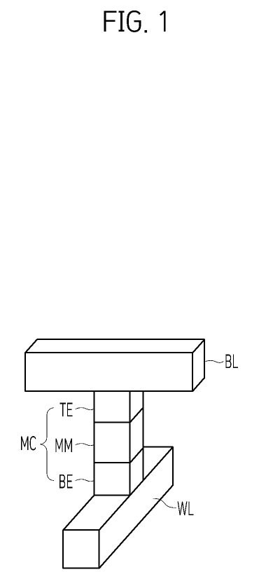

FIG. 1 is a diagram for describing a memory cell of a memory device according to an embodiment of the present disclosure.

Referring to FIG. 1, the memory cell MC of the memory device according to an embodiment of the present disclosure may be located between a bit line BL and a word line WL. Further, the memory cell MC may be electrically connected to the bit line BL and the word line WL. Here, although a configuration in which the bit line BL is arranged above the word line WL is illustrated in FIG. 1, the bit line BL may be arranged below the word line WL according to an embodiment. In addition, each of the bit line BL and the word line WL may contain a conductive material.

The memory cell MC may include a first electrode TE, a memory material MM, and a second electrode BE. The memory material MM may be disposed between the first electrode TE and the second electrode BE. Here, each of the first electrode TE and the second electrode BE may contain a conductive material. The memory material MM may change the level of a threshold voltage depending on the direction of current flowing through the memory material MM. The memory material MM may contain chalcogenide-based material.

For example, the second electrode BE may be formed on the word line WL. The memory material MM may be formed on the second electrode BE. The first electrode TE may be formed on the memory material MM. The bit line BL may be formed on the first electrode TE. Here, depending on the position of formation of the first electrode TE and the second electrode BE, the first electrode TE located at a position higher than that of the second electrode BE may be referred to as a top electrode TE, and the second electrode BE located at a position lower than that of the first electrode TE may be referred to as a bottom electrode BE.

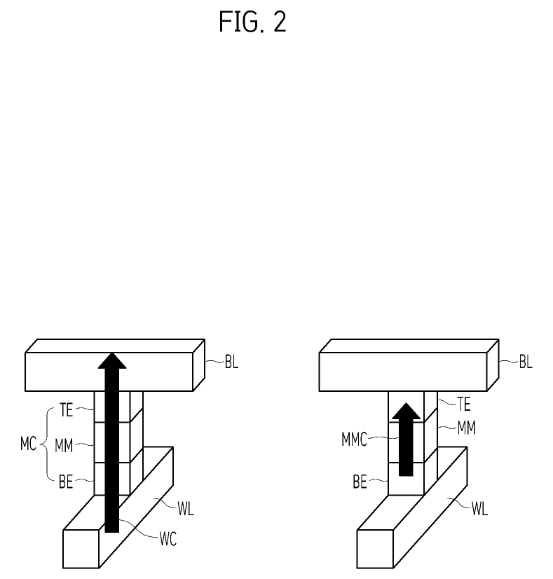

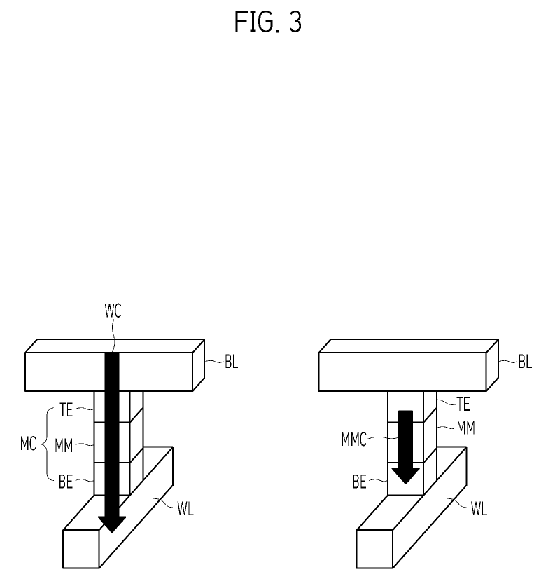

FIGS. 2 and 3 are each diagrams for describing a write operation of a memory device according to an embodiment of the present disclosure.

FIG. 2 is a drawing illustrating a write operation in which a write current WC flows from a word line WL into a bit line BL through a memory cell MC. The write operation may be an operation in which voltages at levels, for which the difference between the voltage levels of the word line WL and the bit line BL is higher than a voltage level required to turn on the memory cell MC in which reset data is stored, are provided to the word line WL and the bit line BL. Here, a voltage higher than that of the bit line BL may be provided to the word line WL.

Such a write operation may be an operation of changing memory material characteristics (MMC) so that current flows through the memory material MM more effectively in a first direction than in a second direction. Here, the first direction is a direction in which current flows from the word line WL into the bit line BL through the memory material MM, and the second direction may be a direction in which current flows from the bit line BL into the word line WL through the memory material MM.

FIG. 3 may be a drawing illustrating a write operation in which a write current WC flows from a bit line BL into a word line WL through a memory cell MC. The write operation may be an operation in which voltages at levels, for which the difference between the voltage levels of the bit line BL and the word line WL is higher than a voltage level required to turn on the memory cell MC in which reset data is stored, are provided to the bit line BL and the word line WL. Here, a voltage higher than that of the word line WL may be provided to the bit line BL.

Such a write operation may be an operation of changing memory material characteristics (MMC) so that current flows through the memory material MM more effectively in a second direction than in a first direction. Here, the first direction is a direction in which current flows from the word line WL into the bit line BL through the memory material MM, and the second direction may be a direction in which current flows from the bit line BL into the word line WL through the memory material MM.

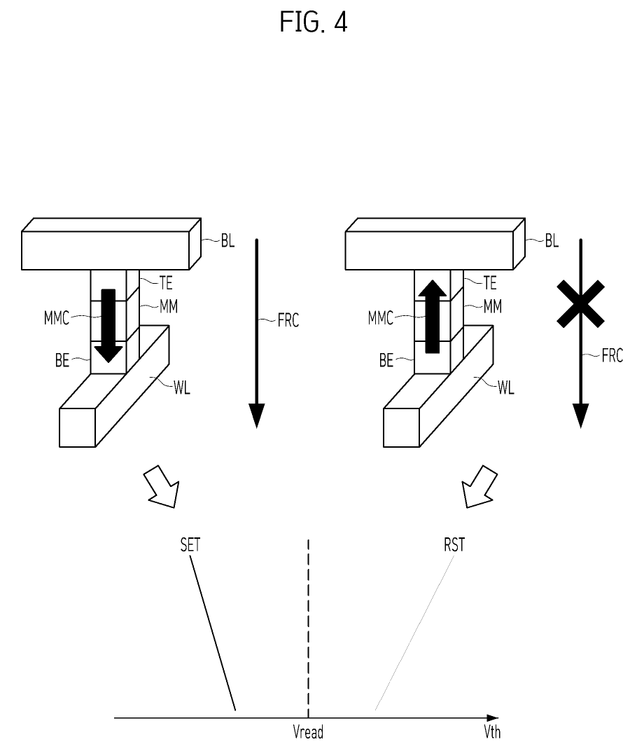

FIG. 4 is a diagram for describing a read operation of a memory device according to an embodiment of the present disclosure.

Referring to FIG. 4, the read operation may be an operation of determining the state of a memory cell MC by providing a voltage at a level higher than that of a word line WL to a bit line BL. Here, the read operation may be an operation of causing a read current FRC, having the same direction as the direction of current WC in the write operation illustrated in FIG. 3, to flow. Also, the difference between the voltage levels of the bit line BL and the word line WL in the read operation may correspond to the level of a read voltage Vread. The read voltage Vread may be a voltage level between the level of the threshold voltage of the memory cell MC corresponding to the write operation of FIG. 2 and the level of the threshold voltage of the memory cell MC corresponding to the write operation of FIG. 3.

Therefore, when the read operation is performed on a memory cell MC, the memory material characteristics (MMC) of which have changed, as illustrated in FIG. 4, through the write operation of causing the write current WC to flow from the bit line BL into the word line WL, as illustrated in FIG. 3, the read current FRC may flow from the bit line BL into the word line WL through a turned-on memory cell MC. Here, because the level of the threshold voltage of the memory cell MC, the memory material characteristics (MMC) of which have changed due to the write operation such as that illustrated in FIG. 3, is lower than that of the read voltage Vread, the memory cell MC may be turned on.

Meanwhile, when the read operation is performed on the memory cell MC, the memory material characteristics (MMC) of which have changed due to the write operation such as that illustrated in FIG. 2, as illustrated in FIG. 4, the read current FRC may not substantially flow. Here, because the level of the threshold voltage of the memory cell MC, the memory material characteristics (MMC) of which have changed due to the write operation such as that illustrated in FIG. 2, is higher than that of the read voltage Vread, the memory cell MC may not be turned on. Therefore, the read current FRC may not substantially flow.

A memory cell MC having a threshold voltage at a level lower than that of the read voltage Vread may be considered to be in a set state SET, and a memory cell MC having a threshold voltage at a level higher than that of the read voltage Vread may be considered to be in a reset state RST.

That is, the state of the memory cell MC may be written to a set state SET through the write operation such as that illustrated in FIG. 3. Also, the state of the memory cell MC may be written to a reset state RST through the write operation such as that illustrated in FIG. 2. Here, the write operation of writing (e.g., changing) the state of the memory cell MC to the set state SET may be referred to as a set write operation, and the write operation of writing (e.g., changing) the state of the memory cell MC to the reset state RST may be referred to as a reset write operation.

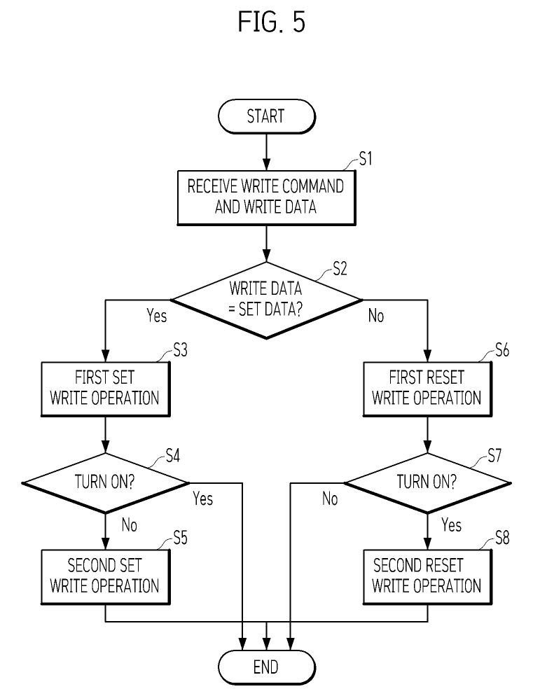

FIG. 5 is a flowchart for describing a method of operating a memory device according to an embodiment of the present disclosure.

Referring to FIG. 5, the method of operating a memory device according to an embodiment of the present disclosure may include a write command and write data reception step S1, a write data determination step S2, a first set write operation step S3, a first turn-on verification step S4, a second set write operation step S5, a first reset write operation step S6, a second turn-on verification step S7, and a second reset write operation step S8.

The write command and write data reception step S1 may include the step of receiving a write command and write data from an external device (e.g., controller (not illustrated)).

The write data determination step S2 may include the step of determining whether the write data is set data.

When it is determined in the write data determination step S2 that the write data is set data (in the case of Yes), the first set write operation step S3 may be performed.

On the other hand, when it is determined in the write data determination step S2 that the write data is reset data (in the case of No), the first reset write operation step S6 may be performed.

Here, the write data determination step S2 may also include the step of determining whether the write data is reset data. In the case of the write data determination step S2 of determining whether the write data is reset data, when it is determined that the write data is the reset data, the first reset write operation step S6 may be performed. Also, in the case of the write data determination step S2 of determining whether the write data is reset data, when it is determined that the write data is set data, the first set write operation step S3 may be performed.

The method in FIG. 5 includes performing a first set write operation on a memory cell at S3. In some embodiments, the first set write operation step S3 may include an operation of writing (e.g., changing) the state of the memory cell to a set state SET. For example, the first set write operation step S3 may include providing a first voltage to a bit line BL and a second voltage to a word line WL, such that the first voltage is higher than the second voltage as illustrated in FIG. 3. Here, a difference between the first and second voltages may be higher than the threshold voltage of the memory cell MC in a reset state RST.

The first turn-on verification step S4 may include the step of verifying whether the memory cell MC, on which the first set write operation step S3 has been performed, has been turned on by providing a voltage at a level lower than that of the read voltage Vread to the memory cell MC. Here, in the first turn-on verification step S4, a voltage at a level higher than that of the word line WL may be applied to the bit line BL.

That is, the first turn-on verification step S4 may be the step of performing an operation by adjusting the levels of voltages respectively applied to the bit line BL and the word line WL so that the bit line BL and the word line WL have a voltage difference lower than the voltage difference between the bit line BL and the word line WL in the first set write operation step S3. For example, the voltage level of the bit line BL in the first turn-on verification step S4 may be lower than the voltage level of the bit line BL in the first set write operation step S3. The voltage level of the word line WL in the first turn-on verification step S4 may be higher than the voltage level of the word line WL in the first set write operation step S3.

When it is verified in the first turn-on verification step S4 that the memory cell MC has been turned on (in the case of Yes), the method of operating the memory device according to the embodiment in FIG. 5 may be terminated. Here, it may be determined that the change of the state of the memory cell MC to the set state SET has been completed.

On the other hand, when it is verified in the first turn-on verification step S4 that the memory cell MC has not been turned on (in the case of No), that is, the memory cell MC is in a turned-off state, the second set write operation S5 may be performed. Here, it may be determined that the change of the state of the memory cell MC to the set state SET has not been completed.

The second set write operation step S5 may include the step of performing an operation of writing (e.g., changing) the state of the memory cell MC to the set state SET by applying a voltage higher than that of the word line WL to the bit line BL. Here, the difference between the voltage levels of the bit line BL and the word line WL in the second set write operation step S5 may be at a level higher than that of the threshold voltage of the memory cell MC in a reset state RST. Further, a first difference between the voltages of the bit line BL and the word line WL in the second set write operation step S5 may be substantially equal to a second difference between the voltages of the bit line BL and the word line WL in the first set write operation step S3. For example, an absolute difference between the first and second differences may be not greater than 5 %, or 3 %, or 1 % of an average of the first and second differences. The voltage level of the bit line BL in the second set write operation step S5 may be substantially equal to the voltage level of the bit line BL in the first set write operation step S3. The voltage level of the word line WL in the second set write operation step S5 may be substantially equal to the voltage level of the word line WL in the first set write operation step S3.

The method in FIG. 5 includes performing a first reset write operation on a memory cell at S6. In some embodiments, the first reset write operation step S6 may include an operation of writing (e.g., changing) the state of the memory cell to a reset state RST. For example, the first reset write operation step S6 may include providing a first voltage to the word line WL and a second voltage to the bit line BL, such that the first voltage is higher than the second voltage as illustrated in FIG. 2. Here, a difference between the first and second voltages may be higher than the threshold voltage of the memory cell MC in a reset state RST.

The second turn-on verification step S7 may include the step of verifying whether the memory cell MC, on which the first reset write operation step S6 has been performed, has been turned on by providing a voltage at a level higher than that of the read voltage Vread to the memory cell MC. Here, in the second turn-on verification step S7, a voltage at a level higher than that of the word line WL may be applied to the bit line BL.

That is, the second turn-on verification step S7 may be the step of performing an operation by adjusting the levels of voltages respectively applied to the bit line BL and the word line WL so that the bit line BL and the word line WL have a voltage difference lower than the voltage difference between the bit line BL and the word line WL in the first reset write operation step S6. For example, the voltage level of the bit line BL in the second turn-on verification step S7 may be higher than the voltage level of the bit line BL in the first reset write operation step S6. The voltage level of the word line WL in the second turn-on verification step S7 may be lower than the voltage level of the word line WL in the first reset write operation step S6.

When it is verified in the second turn-on verification step S7 that the memory cell MC has not been turned on (in the case of No), that is, the memory cell MC is in a turned-off state, the method of operating the memory device according to the embodiment in FIG. 5 may be terminated. Here, it may be determined that the change of the state of the memory cell MC to the reset state RST has been completed.

On the other hand, when it is verified in the second turn-on verification step S7 that the memory cell MC has been turned on (in the case of Yes), the second reset write operation S8 may be performed. Here, it may be determined that the change of the state of the memory cell MC to the reset state RST has not been completed.

The second reset write operation step S8 may include the step of performing an operation of writing (e.g., changing) the state of the memory cell MC to the reset state RST by applying a voltage higher than that of the bit line BL to the word line WL. Here, the difference between the voltages of the bit line BL and the word line WL in the second reset write operation step S8 may be higher than the threshold voltage of the memory cell MC in the reset state RST. Further, the difference between the voltages of the bit line BL and the word line WL in the second reset write operation step S8 may be substantially equal to the difference between the voltages of the bit line BL and the word line WL in the first reset write operation step S6. The voltage level of the bit line BL in the second reset write operation step S8 may be substantially equal to the voltage level of the bit line BL in the first reset write operation step S6. The voltage level of the word line WL in the second reset write operation step S8 may be substantially equal to the voltage level of the word line WL in the first reset write operation step S6.

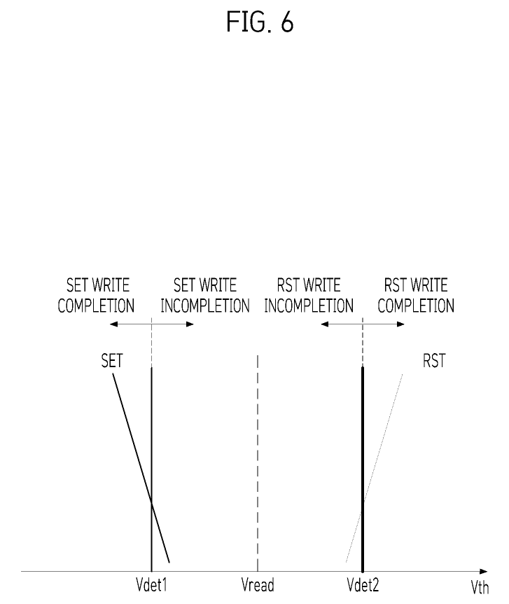

FIG. 6 is a diagram for describing a turn-on verification operation of a memory device according to an embodiment of the present disclosure.

Referring to FIG. 6, a first turn-on verification voltage Vdet1 may be lower than the level of a read voltage Vread. A second turn-on verification voltage Vdet2 may be higher than the level of the read voltage Vread.

The first turn-on verification voltage Vdet1 may be a voltage used in the first turn-on verification step S4 of FIG. 5. In some embodiments, the first turn-on verification step S4 may include verifying whether the memory cell MC is turned on or off based on the first turn-on verification voltage Vdet1. As described above, the first turn-on verification step S4 may include the step of verifying whether the memory cell MC, on which the first set write operation step S3 has been performed, has been turned on, by providing a voltage at a level lower than that of the read voltage Vread, that is, the first turn-on verification voltage Vdet1, to the memory cell MC. Here, in the first turn-on verification step S4, a voltage at a level higher than that of the word line WL may be applied to the bit line BL, and the difference between the voltage levels of the bit line BL and the word line WL may correspond to the level of the first turn-on verification voltage Vdet1. For example, the first turn-on verification step S4 may include providing a third voltage to the bit line BL and a fourth voltage to the word line WL, such that the third voltage is higher than the fourth voltage and a difference between the third and fourth voltages corresponds to the first turn-on verification voltage Vdet1.

When it is verified whether the memory cell MC, on which the first set write operation step S3 has been performed, has been turned on by providing the first turn-on verification voltage Vdet1 to the memory cell MC, the memory cell MC may be turned on in the case where the level of the threshold voltage of the memory cell MC is lower than the level of the first turn-on verification voltage Vdet1. Here, when it is verified that the memory cell MC has been turned on, it may be determined that the set write operation on the memory cell MC has been completed.

On the other hand, when it is verified whether the memory cell MC, on which the first set write operation step S3 has been performed, has been turned on by providing the first turn-on verification voltage Vdet1 to the memory cell MC, the memory cell MC cannot be turned on in the case where the level of the threshold voltage of the memory cell MC is higher than the level of the first turn-on verification voltage Vdet1. Here, when it is not verified that the memory cell MC has been turned on, that is, when it is verified that the memory cell MC has been turned off, it may be determined that the set write operation on the memory cell MC has not been completed.

The second turn-on verification voltage Vdet2 may be a voltage used in the second turn-on verification step S7 of FIG. 5. In some embodiments, the second turn-on verification step S7 may include verifying whether the memory cell MC is turned on or off based on the second turn-on verification voltage Vdet2. As described above, the second turn-on verification step S7 may include the step of verifying whether the memory cell MC, on which the first reset write operation step S6 has been performed, has been turned on, by providing a voltage at a level higher than that of the read voltage Vread, that is, the second turn-on verification voltage Vdet2, to the memory cell MC. Here, in the second turn-on verification step S7, a voltage at a level higher than that of the word line WL may be applied to the bit line BL, and the difference between the voltage levels of the bit line BL and the word line WL may correspond to the level of the second turn-on verification voltage Vdet2. For example, the second turn-on verification step S7 may include providing a third voltage to the bit line BL and a fourth voltage to the word line WL, such that the third voltage is higher than the fourth voltage, and a difference between the third and fourth voltage levels corresponds to the second turn-on verification voltage Vdet2.

When it is verified whether the memory cell MC, on which the first reset write operation step S6 has been performed, has been turned on by providing the second turn-on verification voltage Vdet2 to the memory cell MC, the memory cell MC may be turned on in the case where the level of the threshold voltage of the memory cell MC is lower than the level of the second turn-on verification voltage Vdet2. Here, when it is verified that the memory cell MC has been turned on, it may be determined that the reset write operation on the memory cell MC has not been completed. When the memory cell has been verified as turned on at S7, the method in FIG. 5 may perform the second reset write operation at S8.

On the other hand, when it is not verified whether the memory cell MC, on which the first reset write operation step S6 has been performed, has been turned on by providing the second turn-on verification voltage Vdet2 to the memory cell MC, the memory cell MC cannot be turned on in the case where the level of the threshold voltage of the memory cell MC is higher than the level of the second turn-on verification voltage Vdet2. Here, when it is not verified that the memory cell MC has been turned on, that is, when it is verified that the memory cell MC has been turned off, it may be determined that the reset write operation on the memory cell MC has been completed. When the memory cell MC has been verified as turned off at S7, the method in FIG. 5 may skip the second reset write operation at S8.

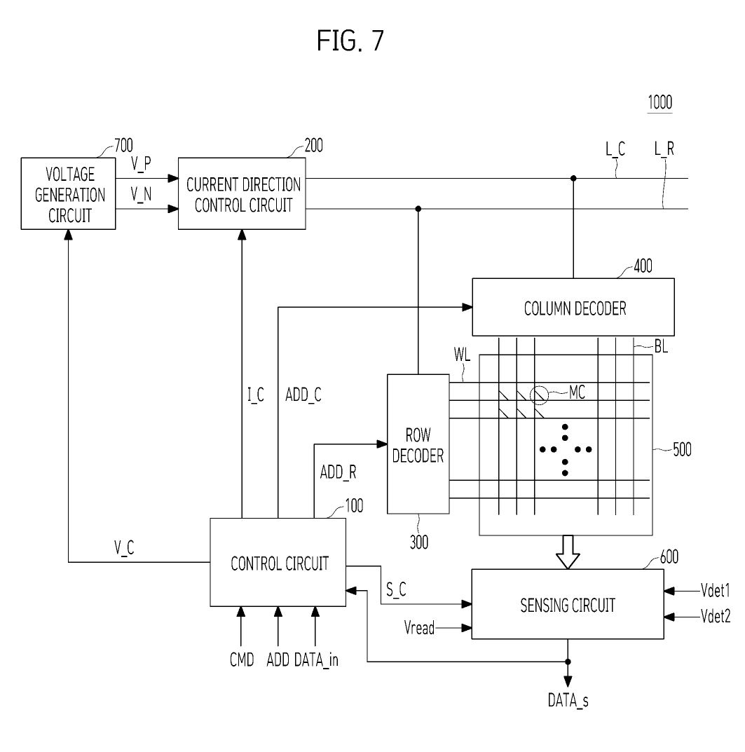

FIG. 7 is a diagram for describing the configuration of a memory device according to an embodiment of the present disclosure.

Referring to FIG. 7, a semiconductor device 1000 according to an embodiment of the present disclosure may include a control circuit 100, a current direction control circuit 200, a row decoder 300, a column decoder 400, a memory cell array 500, a sensing circuit 600, and a voltage generation circuit 700.

The control circuit 100 may store data in the memory cell array 500 or may sense data stored in the memory cell array 500 through the sensing circuit 600 to output sensed results as sensing data DATA_s, by controlling the current direction control circuit 200, the row decoder 300, the column decoder 400, and the voltage generation circuit 700 based on a command CMD, an address signal ADD, and write data DATA_in. Here, an operation of storing data in the memory cell array 500 may be referred to as a write operation, and an operation of sensing data stored in the memory cell array 500 and outputting the sensed data to the outside of the semiconductor device 1000 may be referred to as a read operation.

For example, the control circuit 100 which performs the write operation or the read operation may generate a current direction control signal I_C, a row address signal ADD_R, a column address signal ADD_C, and a voltage level control signal V_C based on the command CMD, the address signal ADD, and the write data DATA_in.

More specifically, for example, the control circuit 100 may generate the current direction control signal I_C and the voltage level control signal V_C based on the command CMD and the write data DATA_in, provide the current direction control signal I_C to the current direction control circuit 200, and provide the voltage level control signal V_C to the voltage generation circuit 700.

The control circuit 100 may generate the row address signal ADD_R and the column address signal ADD_C based on the command CMD and the address signal ADD, provide the row address signal ADD_R to the row decoder 300, and provide the column address signal ADD_C to the column decoder 400.

Also, the control circuit 100 according to an embodiment of the present disclosure may generate a sensing control signal S_C instructing one of a first turn-on verification voltage Vdet1 and a second turn-on verification voltage Vdet2 to be selected depending on the write data DATA_in and provide the generated sensing control signal S_C to the sensing circuit 600, during a write operation based on the command CMD and the write data DATA_in. In addition, the control circuit 100 may control a write operation to be additionally performed depending on the sensing data DATA_s sensed by the sensing circuit 600 based on one of the first and second turn-on verification voltages Vdet1 and Vdet2 during a write operation. Here, when the write operation performed based on the command CMD and the write data DATA_in is referred to as a first write operation, a write operation performed based on data DATA_s sensed during the first write operation may be referred to as a second write operation. Also, the first write operation may include one or both of a first set write operation and a first reset write operation, and the second write operation may include one or both of a second set write operation and a second reset write operation.

The current direction control circuit 200 may selectively provide a positive bias voltage V_P and a negative bias voltage V_N to a row voltage line L_R and a column voltage line L_C, respectively, based on the current direction control signal I_C.

For example, when the positive bias voltage V_P is provided to the row voltage line L_R based on the current direction control signal I_C, the current direction control circuit 200 may provide the negative bias voltage V_N to the column voltage line L_C. Further, when the positive bias voltage V_P is provided to the column voltage line L_C based on the current direction control signal I_C, the current direction control circuit 200 may provide the negative bias voltage V_N to the row voltage line L_R.

The row decoder 300 may select at least one of a plurality of word lines WL based on the row address signal ADD_R, and may drive the selected word line WL to the voltage level of the row voltage line L_R.

The column decoder 400 may select at least one of a plurality of bit lines BL based on the column address signal ADD_C, and may drive the selected bit line BL to the voltage level of the column voltage line L_C.

The memory cell array 500 may include a plurality of memory cells MC, and may be an area in which the plurality of word lines WL and the plurality of bit lines BL intersect. Here, each memory cell MC may be located at a position where one word line WL and one bit line BL intersect. Each memory cell MC may be electrically connected between the word line WL and the bit line BL. Also, each memory cell MC may store data in a set state or a reset state depending on the polarities of voltages provided from the word line WL and the bit line BL, respectively. That is, the state of the memory cell MC may be changed to the set or reset state depending on the direction of current flowing through the memory cell MC. The memory cell MC may be a self-selecting memory containing a chalcogenide-based element or material.

The sensing circuit 600 may detect data stored in the corresponding memory cell MC through the word line WL or the bit line BL, and may output the detected data as sensing data DATA_s. The sensing circuit 600 may detect the data stored in the memory cell MC based on a read voltage Vread and output the detected data as sensing data DATA_s during a read operation. Meanwhile, the sensing circuit 600 may select one of the first turn-on verification voltage Vdet1 and the second turn-on verification voltage Vdet2 based on the sensing control signal S_C, detect the data stored in the memory cell MC based on the selected voltage, and output the detected data as sensing data DATA_s during a write operation. More specifically, for example, the control circuit 100 may receive a write command CMD and write data DATA_in that is set data. Here, the control circuit 100 may generate a sensing control signal S_C instructing the first turn-on verification voltage Vdet1 to be selected between the first and second turn-on verification voltages Vdet1 and Vdet2, and may provide the sensing control signal S_C to the sensing circuit 600. The sensing circuit 600 may detect the data stored in the memory cell MC based on the first turn-on verification voltage Vdet1, and may provide detected results as sensing data DATA_s to the control circuit 100. Meanwhile, the control circuit 100 may receive the write command CMD and write data DATA_in that is reset data. Here, the control circuit 100 may generate a sensing control signal S_C instructing the second turn-on verification voltage Vdet2 to be selected between the first and second turn-on verification voltages Vdet1 and Vdet2, and may provide the sensing control signal S_C to the sensing circuit 600. The sensing circuit 600 may detect the data stored in the memory cell MC based on the second turn-on verification voltage Vdet2, and may provide detected results as sensing data DATA_s to the control circuit 100.

The voltage generation circuit 700 may generate the positive bias voltage V_P and the negative bias voltage V_N based on the voltage level control signal V_C provided from the control circuit 100. Here, the level difference between the positive bias voltage V_P and the negative bias voltage V_N, which are generated by the voltage generation circuit 700 during a write operation, may be greater than the level of the threshold voltage of a memory cell MC in a reset state. Here, the level difference between the positive bias voltage V_P and the negative bias voltage V_N, which are generated by the voltage generation circuit 700 during a read operation, may be a level between the level of the threshold voltage of a memory cell MC in a set state and the level of the threshold voltage of a memory cell MC in a reset state.

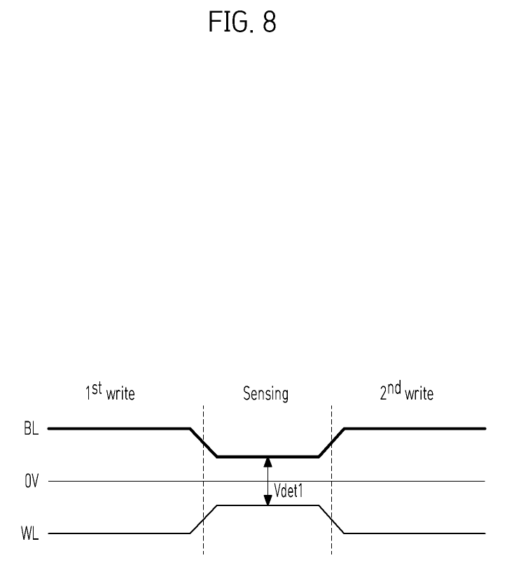

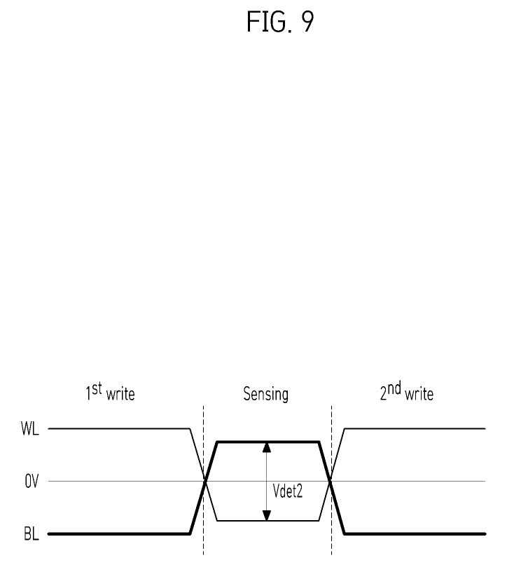

An operation of the memory device 1000 according to the embodiment of FIG. 7, will be described below with reference to FIGS. 5 and 7-9. Here, FIGS. 8 and 9 are each diagrams for describing changes in the levels of a bit line and a word line depending on the operation of the memory device according to an embodiment of the present disclosure.

Referring to FIG. 5, the write command and write data reception step S1 may be performed. Referring to FIG. 7, a command CMD, an address signal ADD, and write data DATA_in may be received by the control circuit 100. Here, the command CMD may be a write command.

Referring to FIG. 5, the write data determination step S2 may be performed. Referring to FIG. 7, the control circuit 100 may determine whether the write data DATA_in is set data or reset data.

First, the case where the write data DATA_in is set data will be described.

Referring to FIG. 5, when it is determined in the write data determination step S2 that the write data DATA_in is the set data (in the case of Yes), the first set write operation step S3 may be performed. For example, the method in FIG. 5 may include performing a first set write operation on a first memory cell at S3 upon determining that the write data DATA_in is the set data at S2. Referring to FIG. 7, when it is determined that the write data DATA_in is the set data, the control circuit 100 may control the current direction control circuit 200, the row decoder 300, the column decoder 400, and the voltage generation circuit 700 to perform a first set write operation. The control circuit 100 may control the voltage generation circuit 700 to generate the positive bias voltage V_P and the negative bias voltage V_N by providing the voltage level control signal V_C to the voltage generation circuit 700. Here, the level difference between the positive bias voltage V_P and the negative bias voltage V_N may be greater than the level of the threshold voltage of the memory cell MC in a reset state. In addition, the control circuit 100 may control the current direction control circuit 200 so that the positive bias voltage V_P is provided to the column voltage line L_C and the negative bias voltage V_N is provided to the row voltage line L_R by providing the current direction control signal I_C to the current direction control circuit 200. The row decoder 300 may select at least one of a plurality of word lines WL based on the row address signal ADD_R provided from the control circuit 100, and may drive the selected word line WL to the voltage level of the row voltage line L_R. The column decoder 400 may select at least one of a plurality of bit lines BL based on the column address signal ADD_C provided from the control circuit 100, and may drive the selected bit line BL to the voltage level of the column voltage line L_C. Here, the set write operation may be performed on the memory cell MC, which is electrically connected between the selected bit line BL and the selected word line WL, as illustrated in FIG. 3, and thus the state of the memory cell MC may be written (e.g., changed) to a set state SET. Furthermore, the set write operation may be an operation of writing (e.g., changing) the state of the memory cell MC to the set state by applying a voltage at a level higher than that of the selected word line WL to the selected bit line BL.

Referring to FIG. 5, after a first set write operation is performed based on the write command and write data DATA_in, the first turn-on verification step S4 may be performed. In this case, the first turn-on verification step S4 may be the step of verifying whether the memory cell MC, on which the first set write operation has been performed, has been turned on, based on the first turn-on verification voltage Vdet1. For example, the method in FIG. 5 may include verifying whether the memory cell MC is turned on or off based on the first turn-on verification voltage Vdet1 at S4. Referring to FIG. 7, the control circuit 100 may control the sensing circuit 600 to sense the memory cell MC, on which the set write operation has been performed, based on the first turn-on verification voltage Vdet1 by providing the sensing control signal S_C to the sensing circuit 600. For example, the sensing circuit 600 in FIG. 7 may verify whether the memory cell MC is turned on or off based on the first turn-on verification voltage Vdet1, and output turn-on information of the memory cell MC as sensing data DATA_s under control of the control circuit 100. Here, when the sensing circuit 600 senses that the level of the threshold voltage of the memory cell MC is higher than the level of the first turn-on verification voltage Vdet1, the sensing circuit 600 may provide sensing data DATA_s, including information indicating that the memory cell MC has been turned on, to the control circuit 100. On the other hand, when the sensing circuit 600 senses that the level of the threshold voltage of the memory cell MC is lower than the level of the first turn-on verification voltage Vdet1, the sensing circuit 600 may provide sensing data DATA_s, including information indicating that the memory cell MC has not been turned on, that is, the memory cell MC has been turned off, to the control circuit 100. Here, the level of the first turn-on verification voltage Vdet1 may be lower than the level of the read voltage Vread, and the first turn-on verification step S4 may include an operation of providing a voltage at a level higher than that of the word line WL to the bit line BL. Therefore, the current direction control circuit 200 may provide the positive bias voltage V_P to the column voltage line L_C and provide the negative bias voltage V_N to the row voltage line L_R in the first turn-on verification step S4 depending on the current direction control signal I_C of the control circuit 100.

In some embodiments, the method in FIG. 5 may include determining whether to perform a second set write operation on a first memory cell (e.g., the memory cell MC) in response to a first verification result on the memory cell MC. Referring to FIG. 5, when it is verified in the first turn-on verification step S4 that the memory cell MC, on which the first set write operation has been performed, has been turned on (in the case of YES), the operation of the memory device may be terminated. For example, when the memory cell MC has been verified as turned on at the first turn-on verification step S4, the method in FIG. 5 may skip the second set write operation at S5. Referring to FIG. 7, the control circuit 100 may determine that the set write operation on the selected memory cell MC has been completed.

Referring to FIG. 5, when it is verified in the first turn-on verification step S4 that the memory cell MC, on which the first set write operation has been performed, has not been turned on, that is, the memory cell MC has been turned off (in the case of No), the second set write operation S5 may be performed. For example, when the memory cell MC has been verified as turned off at the first turn-on verification step S4, the method in FIG. 5 may perform the second set write operation at S5. Referring to FIG. 7, when it is not verified that the memory cell MC has been turned on (e.g., when the memory cell has been verified as turned off), the control circuit 100 may control the current direction control circuit 200, the row decoder 300, the column decoder 400, and the voltage generation circuit 700 to perform the second set write operation. The control circuit 100 may control the voltage generation circuit 700 to generate the positive bias voltage V_P and the negative bias voltage V_N by providing the voltage level control signal V_C to the voltage generation circuit 700. Here, the level difference between the positive bias voltage V_P and the negative bias voltage V_N may be greater than the level of the threshold voltage of the memory cell MC in a reset state. In addition, the control circuit 100 may control the current direction control circuit 200 so that the positive bias voltage V_P is provided to the column voltage line L_C and the negative bias voltage V_N is provided to the row voltage line L_R by providing the current direction control signal I_C to the current direction control circuit 200. The row decoder 300 may select at least one of a plurality of word lines WL based on the row address signal ADD_R provided from the control circuit 100, and may drive the selected word line WL, that is, the word line WL in the first set write operation, to the voltage level of the row voltage line L_R.

The column decoder 400 may select at least one of a plurality of bit lines BL based on the column address signal ADD_C provided from the control circuit 100, and may drive the selected bit line BL, that is, the bit line BL in the first set write operation, to the voltage level of the column voltage line L_C. Here, a set write operation may be additionally performed on the memory cell MC electrically connected between the selected bit line BL and the selected word line WL, that is, the memory cell MC on which the first set write operation has been performed, and thus the state of the memory cell MC may be written to the set state SET. Furthermore, the set write operation may be an operation of writing (e.g., changing) the state of the memory cell MC to the set state by applying a voltage at a level higher than that of the selected word line WL to the selected bit line BL. Thereafter, the control circuit 100 may determine that the set write operation on the selected memory cell MC has been completed.

FIG. 8 illustrates changes in the voltage levels of a selected bit line BL and a selected word line WL when the memory device according to an embodiment of the present disclosure performs a first set write operation corresponding to a command, a first turn-on verification operation, and a second set write operation corresponding to the result of the first turn-on verification operation.

During the first set write operation (1st Write), a voltage at a level higher than that of the word line WL may be provided to the bit line BL. In some embodiments, the difference between the voltage levels of the bit line BL and the word line WL may correspond to the level of the threshold voltage of a memory cell MC in a reset state. In some embodiments, the difference between the voltage levels of the bit line BL and the word line WL may be higher than the threshold voltage of a memory cell MC in a reset state.

During the first turn-on verification operation (Sensing), whether the memory cell MC has been turned on may be sensed based on a first turn-on verification voltage Vdet1. Here, during the first turn-on verification operation, a voltage at a level higher than that of the word line WL may be provided to the bit line BL. The difference between the voltage levels of the bit line BL and the word line WL may correspond to the first turn-on verification voltage Vdet1, and the first turn-on verification voltage Vdet1 may have a level lower than that of a read voltage Vread.

During the second set write operation (2nd write), a voltage at a level higher than that of the word line WL may be provided to the bit line BL. In some embodiments, the difference between the voltage levels of the bit line BL and the word line WL may correspond to the level of the threshold voltage of a memory cell MC in a reset state. In some embodiments, the difference between the voltage levels of the bit line BL and the word line WL may be higher than the threshold voltage of a memory cell MC in a reset state.

Therefore, when the memory device according to an embodiment of the present disclosure performs the first set write operation corresponding to the command, the first turn-on verification operation, and the second set write operation corresponding to the result of the first turn-on verification operation, changes in the voltage levels of the selected bit line BL and the selected word line WL may include a change in the level of the positive bias voltage V_P provided to the bit line BL and a change in the level of the negative bias voltage V_N provided to the word line WL.

Second, the case where write data DATA_in is reset data will be described below.

Referring to FIG. 5, when it is determined in the write data determination step S2 that the write data DATA_in is reset data (in the case of No), the first reset write operation step S6 may be performed. For example, the method in FIG. 5 may include performing a first reset write operation on a second memory cell at S6 upon determining that the write data DATA_in is the reset data at S2. Referring to FIG. 7, when it is determined that the write data DATA_in is the reset data, the control circuit 100 may control the current direction control circuit 200, the row decoder 300, the column decoder 400, and the voltage generation circuit 700 to perform a first reset write operation. The control circuit 100 may control the voltage generation circuit 700 to generate the positive bias voltage V_P and the negative bias voltage V_N by providing the voltage level control signal V_C to the voltage generation circuit 700. Here, the level difference between the positive bias voltage V_P and the negative bias voltage V_N may be greater than the level of the threshold voltage of the memory cell MC in a reset state. In addition, the control circuit 100 may control the current direction control circuit 200 so that the positive bias voltage V_P is provided to the row voltage line L_R and the negative bias voltage V_N is provided to the column voltage line L_C by providing the current direction control signal I_C to the current direction control circuit 200. The row decoder 300 may select at least one of a plurality of word lines WL based on the row address signal ADD_R provided from the control circuit 100, and may drive the selected word line WL to the voltage level of the row voltage line L_R. The column decoder 400 may select at least one of a plurality of bit lines BL based on the column address signal ADD_C provided from the control circuit 100, and may drive the selected bit line BL to the voltage level of the column voltage line L_C. Here, the reset write operation may be performed on the memory cell MC, which is electrically connected between the selected bit line BL and the selected word line WL, as illustrated in FIG. 3, and thus the state of the memory cell MC may be written (e.g., changed) to a reset state RST. Further, the reset write operation may be an operation of writing (e.g., changing) the state of the memory cell MC to the reset state RST by applying a voltage at a level higher than that of the selected bit line BL to the selected word line WL.

Referring to FIG. 5, after the first reset write operation is performed based on the write command and write data DATA_in, the second turn-on verification step S7 may be performed. In this case, the second turn-on verification step S7 may be the step of verifying whether the memory cell MC, on which the first reset write operation has been performed, has been turned on, based on the second turn-on verification voltage Vdet2. For example, the method in FIG. 5 may include verifying whether the memory cell MC is turned on or off based on the second turn-on verification voltage Vdet2 at S7. Referring to FIG. 7, the control circuit 100 may control the sensing circuit 600 to sense the memory cell MC, on which the reset write operation has been performed, based on the second turn-on verification voltage Vdet2 by providing the sensing control signal S_C to the sensing circuit 600. For example, the sensing circuit 600 in FIG. 7 may verify whether the memory cell MC is turned on or off based on the second turn-on verification voltage Vdet2, and output turn-on information of the memory cell MC as sensing data DATA_s under control of the control circuit 100. Here, when the sensing circuit 600 senses that the level of the threshold voltage of the memory cell MC is higher than the level of the second turn-on verification voltage Vdet2, the sensing circuit 600 may provide sensing data DATA_s, including information indicating that the memory cell MC has been turned on, to the control circuit 100. On the other hand, when the sensing circuit 600 senses that the level of the threshold voltage of the memory cell MC is lower than the level of the second turn-on verification voltage Vdet2, the sensing circuit 600 may provide sensing data DATA_s, including information indicating that the memory cell MC has not been turned on, that is, the memory cell MC has been turned off, to the control circuit 100. Here, the level of the second turn-on verification voltage Vdet2 may be higher than the level of the read voltage Vread, and the second turn-on verification step S7 may include an operation of providing a voltage at a level higher than that of the word line WL to the bit line BL. Therefore, the current direction control circuit 200 may provide the positive bias voltage V_P to the column voltage line L_C and provide the negative bias voltage V_N to the row voltage line L_R depending on the current direction control signal I_C of the control circuit 200.

In some embodiments, the method in FIG. 5 may include determining whether to perform a second reset write operation on a second memory cell (e.g., the memory cell) MC in response to a second verification result on the memory cell MC. Referring to FIG. 5, when it is verified in the second turn-on verification step S7 that the memory cell MC, on which the first reset write operation has been performed, has been turned on (in the case of Yes), the second reset write operation S8 may be performed. For example, when the memory cell MC has been verified as turned on at the second turn-on verification step S7, the method in FIG. 5 may perform the second reset write operation at S8. Referring to FIG. 7, when it is verified that the memory cell MC has been turned on (e.g., when the memory cell MC has been verified as turned on), the control circuit 100 may control the current direction control circuit 200, the row decoder 300, the column decoder 400, and the voltage generation circuit 700 to perform the second reset write operation. The control circuit 100 may control the voltage generation circuit 700 to generate the positive bias voltage V_P and the negative bias voltage V_N by providing the voltage level control signal V_C to the voltage generation circuit 700. Here, the level difference between the positive bias voltage V_P and the negative bias voltage V_N may be greater than the level of the threshold voltage of the memory cell MC in a reset state. In addition, the control circuit 100 may control the current direction control circuit 200 so that the positive bias voltage V_P is provided to the row voltage line L_R and the negative bias voltage V_N is provided to the column voltage line L_C by providing the current direction control signal I_C to the current direction control circuit 200. The row decoder 300 may select at least one of a plurality of word lines WL based on the row address signal ADD_R provided from the control circuit 100, and may drive the selected word line WL, that is, the word line WL in the first reset write operation, to the voltage level of the row voltage line L_R. The column decoder 400 may select at least one of a plurality of bit lines BL based on the column address signal ADD_C provided from the control circuit 100, and may drive the selected bit line BL, that is, the bit line BL in the first reset write operation, to the voltage level of the column voltage line L_C. Here, a reset write operation may be additionally performed on the memory cell MC electrically connected between the selected bit line BL and the selected word line WL, that is, the memory cell MC on which the first reset write operation has been performed, and thus the state of the memory cell MC may be changed to the reset state RST.

Further, the reset write operation may be an operation of changing the state of the memory cell MC to the reset state by applying a voltage at a level higher than that of the selected bit line BL to the selected word line WL. Thereafter, the control circuit 100 may determine that the reset write operation on the selected memory cell MC has been completed.

Referring to FIG. 5, when it is verified in the second turn-on verification step S7 that the memory cell MC, on which the first reset write operation has been performed, has not been turned on, that is, the memory cell MC has been turned off (in the case of No), the operation of the memory device according to an embodiment of the present disclosure may be terminated. For example, when the memory cell MC has been verified as turned off at the second turn-on verification step S7, the method in FIG. 5 may skip the second reset write operation at S8. Referring to FIG. 7, the control circuit 100 may determine that the reset write operation on the selected memory cell MC has been completed.

FIG. 9 illustrates changes in the voltage levels of a selected bit line BL and a selected word line WL when the memory device according to an embodiment of the present disclosure performs a first reset write operation corresponding to a command, a second turn-on verification operation, and a second reset write operation corresponding to the result of the second turn-on verification operation.

During the first reset write operation (1st Write), a voltage at a level higher than that of the bit line BL may be provided to the word line WL. In some embodiments, the difference between the voltage levels of the bit line BL and the word line WL may correspond to the level of the threshold voltage of a memory cell MC in a reset state. In some embodiments, the difference between the voltage levels of the bit line BL and the word line WL may be higher than the threshold voltage of a memory cell MC in a reset state.

During the second turn-on verification operation (Sensing), whether the memory cell MC has been turned on may be sensed based on the second turn-on verification voltage Vdet2. Here, during the second turn-on verification operation, a voltage at a level higher than that of the word line WL may be provided to the bit line BL. The difference between the voltage levels of the bit line BL and the word line WL may correspond to the second turn-on verification voltage Vdet2, and the second turn-on verification voltage Vdet2 may be a voltage at a level higher than that of a read voltage Vread.

During the second reset write operation (2nd write), a voltage at a level higher than that of the bit line BL may be provided to the word line WL. In some embodiments, the difference between the voltage levels of the bit line BL and the word line WL may correspond to the level of the threshold voltage of a memory cell MC in a reset state. In some embodiments, the difference between the voltage levels of the bit line BL and the word line WL may be higher than the threshold voltage of a memory cell MC in a reset state.

Therefore, when the memory device according to an embodiment of the present disclosure performs the first reset write operation corresponding to the command, the second turn-on verification operation, and the second reset write operation corresponding to the result of the second turn-on verification operation, changes in the voltage levels of the selected bit line BL and the selected word line WL may occur such that a negative bias voltage, a positive bias voltage, and a negative bias voltage are sequentially provided to the bit line BL, and a positive bias voltage, a negative bias voltage, and a positive bias voltage are sequentially provided to the word line WL.

When it is determined that a write operation (including a set write operation and a reset write operation) corresponding to a command has not been completed, the memory device according to an embodiment of the present disclosure may additionally perform a write operation, thus improving the distribution of memory cells.

Embodiments of the present disclosure may improve the distribution of memory cells. In some embodiments, when at least one of memory cells that has been written to a set state in a first set write operation is verified as turned off, a second set write operation may be performed on such memory cells. In some embodiments, when at least one of memory cells that has been written to a reset state in a first reset write operation is verified as turned on, a second reset write operation may be performed on such memory cells. As a result, distributions of memory cells written to the set state and the reset state according to embodiments of the present disclosure may be improved to ensure sufficient read margin.

Although some embodiments have been described above with reference to the accompanying drawings, various embodiments of the present disclosure are not limited to the above-described embodiments. Various substitutions, modifications, and changes according to embodiments may be made by those skilled in the art to which the present disclosure pertains in light of teachings of the present disclosure, and such variations fall within embodiments of the present disclosure.

What is claimed is:

1. A method of operating a memory device, comprising:
receiving a write command;
performing a first write operation on a memory cell;
verifying whether the memory cell is turned on or off based on a turn-on verification voltage; and
determining whether to perform a second write operation on the memory cell in response to a verification result.

2. The method of claim 1, wherein the write command is a set write command, the first write operation is a first set write operation to write the memory cell to a set state, the turn-on verification voltage has a level lower than that of a read voltage, and the second write operation is a second set write operation.

3. The method of claim 2, wherein, performing each of the first and second set write operations on the memory cell includes providing a first voltage to a bit line and a second voltage to a word line, the memory cell being coupled between the bit line and the word line, and
wherein the first voltage is higher than the second voltage, and a difference between the first and second voltages is higher than a threshold voltage of the memory cell in a reset state.

4. The method of claim 2, wherein verifying whether the memory cell is turned on or off comprises providing a third voltage to a bit line and a fourth volage to a word line, the memory cell being coupled between the bit line and the word line, and
wherein the third voltage is higher than the fourth voltage, and a difference between the third and fourth voltages corresponds to the turn-on verification voltage.

5. The method of claim 2, further comprising:
performing the second set write operation when the memory cell has been verified as turned off; and
skipping the second set write operation when the memory cell has been verified as turned on.

6. The method of claim 1, wherein the write command is a reset write command, the first write operation is a first reset write operation to write the memory cell to a reset state, the turn-on verification voltage has a level higher than that of a read voltage, the second write operation is a second reset write operation.

7. The method of claim 6, wherein, performing each of the first and second reset write operations on the memory cell includes providing a first voltage to a word line and a second voltage to a bit line, the memory cell being coupled between the bit line and the word line, and
wherein the first voltage is higher than the second voltage, and a difference between the first and second voltages is higher than a threshold voltage of the memory cell in the reset state.

8. The method of claim 6, wherein verifying whether the memory cell is turned on or off comprises providing a third voltage to a bit line and a fourth voltage to a word line, the memory cell being coupled between the bit line and the word line,
wherein the third voltage is higher than the fourth voltage, and a difference between the third and fourth voltage levels corresponds to the turn-on verification voltage.

9. The method of claim 6, further comprising:
performing the second reset write operation when the memory cell has been verified as turned on; and
skipping the second reset write operation when the memory cell has been verified as turned off.

10. A method of operating a memory device, comprising:
receiving a write command and write data;
determining whether the write data is set data or reset data;
performing a first set write operation on a first memory cell upon determining that the write data is the set data;
performing a first reset write operation on a second memory cell upon determining that the write data is the reset data;
verifying whether the first memory cell is turned on or off based on a first turn-on verification voltage;
verifying whether the second memory cell is turned on or off, based on a second turn-on verification voltage, the second turn-on verification voltage having a level higher than that of the first turn-on verification voltage;
determining whether to perform a second set write operation on the first memory cell in response to a first verification result on the first memory cell; and
determining whether to perform a second reset write operation on the second memory cell in response to a second verification result on the second memory cell.

11. The method of claim 10, wherein performing each of the first set write operation and the second set write operation comprises providing a first voltage to a bit line and a second voltage to a word line, the first memory cell being coupled between the bit line and the word line, and the first voltage is higher than the second voltage.

12. The method of claim 10, wherein verifying whether the first memory cell is turned on or off comprises providing a third voltage to a bit line and a fourth voltage to a word line, the first memory cell being coupled between the bit line and the word line, the third voltage being higher than the fourth voltage, and
wherein verifying whether the second memory cell is turned on or off comprises providing a fifth voltage to the bit line and a sixth voltage to the word line, the second memory cell being coupled between the bit line and the word line, the fifth voltage being higher than the sixth voltage.

13. The method of claim 12, wherein:
a level of the first turn-on verification voltage is lower than that of a read voltage; and
a level of the second turn-on verification voltage is higher than that of the read voltage.

14. The method of claim 13, wherein:
a difference between the third and fourth voltages corresponds to the first turn-on verification voltage; and
a difference between the fifth and sixth voltage levels corresponds to the second turn-on verification voltage.

15. The method of claim 10, wherein performing each of the first reset write operation and the second reset write operation comprises providing a first voltage to a word line and a second voltage to a bit line, the second memory cell being coupled between the bit line and the word line, and the first voltage is higher than the second voltage.

16. A memory device, comprising:
a memory cell;
a control circuit configured to perform a first write operation on the memory cell based on write data and perform a second write operation on the memory cell based on sensing data; and
a sensing circuit configured to verify whether the memory cell is turned on or off based on one of a first turn-on verification voltage and a second turn-on verification voltage and to output turn-on information of the memory cell as the sensing data, under control of the control circuit.

17. The memory device of claim 16, wherein the control circuit is configured to:
when the write data is set data, perform a first set write operation on the memory cell as the first write operation; and
when the memory cell has been verified as turned off, perform a second set write operation on the memory cell as the second write operation.

18. The memory device of claim 16, wherein the control circuit is configured to:
when the write data is reset data, perform a first reset write operation on the memory cell as the first write operation; and
when the memory cell has been verified as turned on, perform a second reset write operation on the memory cell as the second write operation.

19. The memory device of claim 16, wherein the control circuit is configured to, when the write data is set data, control the sensing circuit to verify whether the memory cell is turned on or off based on the first turn-on verification voltage.

20. The memory device of claim 16, wherein the control circuit is configured to, when the write data is reset data, control the sensing circuit to verify whether the memory cell is turned on or off based on the second turn-on verification voltage.
